(19) United States
(12) Patent Application Publication
(10) Pub. No.: US 2024/0429682 A1
(43) Pub. Date: Dec. 26, 2024

(54) High-Speed Vertical Cavity Surface Emitting Laser, Optoelectronic Device with the Same, and Manufacturing Method Thereof

(71) Applicant: Shenzhen Berxel Photonics Co., Ltd., Shenzhen City (CN)

(72) Inventors: Jiaxing Wang, Shenzhen City (CN); Jianqiang Chen, Shenzhen City (CN)

(21) Appl. No.: 18/527,172

(22) Filed: Dec. 1, 2023

(30) Foreign Application Priority Data
Jun. 20, 2023 (CN) 202310727909.6
Jun. 20, 2023 (CN) 202321584140.9

(51) Int. Cl. H01S 5/183; H01S 5/026

(52) U.S. Cl. CPC H01S 5/18311; H01S 5/026; H01S 5/18361; H01S 2301/176

(57) ABSTRACT

The present disclosure provides a high-speed vertical cavity surface emitting laser, an optoelectronic device with the same, and a manufacturing method thereof. The high-speed vertical cavity surface emitting laser includes a substrate layer, a first electrode layer, a first reflector layer, an active layer, an oxide-confined layer, a second reflector layer and a second electrode layer, wherein the first electrode layer is an N-type electrode layer and the second electrode layer is a P-type electrode layer. The oxidation aperture in the oxide-confined layer is drop-shaped.

### CROSS-REFERENCE TO RELATED APPLICATIONS

This application claims priority to Chinese Patent Application Nos. 202310727909.6 filed on Jun. 20, 2023 and 202321584140.9 filed on Jun. 20, 2023, the entire contents of which are incorporated herein by reference.

### TECHNICAL FIELD

The present disclosure generally relates to the technical field of optoelectronic devices, and specifically relates to a high-speed vertical cavity surface emitting laser and an optoelectronic device with the same, and a manufacturing method.

### BACKGROUND

Vertical cavity surface emitting lasers (VCSELs) can be widely used in the fields of optical communication, 3D sensing, laser radar, and the like due to their advantages such as small size, low power consumption, two-dimensional array integration, high modulation rate, and circular beam output. The shape of an oxide aperture in an oxide-confined layer of a VCSEL will affect modes of the laser and further affect important characteristics such as relative intensity noise (RIN) and root mean square (RMS) spectral width.

At present, the oxide aperture of the VCSEL in related technologies is usually circular, with extremely high rotational symmetry, so that two or even more degenerate modes easily occur at a same frequency point. The degenerate modes may compete, so that mode partition noise (MPN) increases, which further increases RIN and degrades consistency of RIN and RMS. As a result, the bit error ratio (BER) of a communication system increases, which seriously affects communication quality.

### SUMMARY

In view of the above defects or deficiencies in related technologies, it is desired to provide a high-speed vertical cavity surface emitting laser and an optoelectronic device with the same, and a manufacturing method, which can reduce relative intensity noise of the laser and improve consistency of the relative intensity noise and root mean square spectral width, thereby solving the problem of increase in bit error ratio due to the relative intensity noise and excessive dispersion, and improving communication quality.

In a first aspect, the present disclosure provides a high-speed vertical cavity surface emitting laser, which includes a substrate layer, a first electrode layer, a first reflector layer, an active layer, an oxide-confined layer, a second reflector layer, and a second electrode layer, where the first electrode layer is an N-type metal electrode layer, the second electrode layer is a P-type metal electrode layer, and an oxide aperture of the oxide-confined layer is drop-shaped.

In one embodiment, the first electrode layer, the first reflector layer, the active layer, the oxide-confined layer, the second reflector layer, and the second electrode layer are sequentially stacked above the substrate layer;

Alternatively, the first electrode layer is located below the substrate layer, while the first reflector layer, the active layer, the oxide-confined layer, the second reflector layer, and the second electrode layer are sequentially stacked above the substrate layer.

In one embodiment, the first reflector layer and the second reflector layer include at least one of a Bragg reflector layer and a high contrast grating layer.

In one embodiment, the active layer includes either a single quantum well layer or a multiple quantum well layer.

In one embodiment, the oxide aperture is disposed in a middle position of the oxide-confined layer.

In one embodiment, the high-speed vertical cavity surface emitting laser further includes a passivation layer, and the passivation layer is located in an area on the second reflector layer without the second electrode layer.

In a second aspect, the present disclosure provides an optoelectronic device, which includes the high-speed vertical cavity surface emitting laser as described in any item of the first aspect.

In a third aspect, the present disclosure provides a manufacturing method for a high-speed vertical cavity surface emitting laser. The method is applied to the high-speed vertical cavity surface emitting laser as described in any item of the first aspect. The method includes:
providing the substrate layer and forming the first reflector layer, the active layer, the oxide-confined layer, and the second reflector layer sequentially above the substrate layer;
setting three Trenches arranged in a preset manner, and exposing the oxide-confined layer through etching, so as to partially oxidize the oxide-confined layer to obtain the drop-shaped oxide aperture; and
filling the etched Trenches with a metal to form the first electrode layer and the second electrode layer, where the first electrode layer is connected to the first reflector layer, and the second electrode layer is connected to the second reflector layer.

In one embodiment, distances between the Trenches are equal or unequal.

In one embodiment, the Trenches have a width of 3 μm to 6 μm.

From the above technical solutions, it can be seen that the present disclosure has the following advantages:

The present disclosure provides a high-speed vertical cavity surface emitting laser and an optoelectronic device with the same, and a manufacturing method, where a drop-shaped oxide aperture in an oxide-confined layer of the high-speed vertical cavity surface emitting laser breaks rotational symmetry of mode partition of a circular oxide aperture, and can reduce generation of multiple degenerate modes at a same frequency point, thereby reducing relative intensity noise of the laser, improving consistency of the relative intensity noise and root mean square spectral width, and significantly improving communication quality.

### BRIEF DESCRIPTION OF FIGURES

After reading detailed descriptions of non-limiting embodiments with reference to the following accompanying drawings, other features, objectives and advantages of the present disclosure will become more apparent.

FIG. 1 is a cross-sectional structure diagram of a high-speed vertical cavity surface emitting laser provided by an embodiment of the present disclosure;

FIG. 2 is a top view of a drop-shaped oxide aperture provided by an embodiment of the present disclosure;

FIG. 3A-3C sequentially show an oxidation simulation diagram corresponding to a drop-shaped oxide aperture, a microscope diagram corresponding to an actual chip, and a near field spot diagram provided by an embodiment of the present disclosure;

FIG. 4 is a cross-sectional structure diagram of another high-speed vertical cavity surface emitting laser provided by an embodiment of the present disclosure;

FIG. 5 is a structural block diagram of an optoelectronic device provided by an embodiment of the present disclosure;

FIG. 6 is a basic flowchart of a manufacturing method for a high-speed vertical cavity surface emitting laser provided by an embodiment of the present disclosure; and

FIG. 7A-7B are schematic diagrams of a drop-shaped design with different aspect ratios provided by an embodiment of the present disclosure.

### REFERENCE NUMERALS

high-speed vertical cavity surface emitting laser 100, substrate layer 101, first electrode layer 102, first reflector layer 103, active layer 104, oxide-confined layer 105, oxide aperture 1051, second reflector layer 106, second electrode layer 107, passivation layer 108, optoelectronic device 200, trench 201, metal 202.

### DETAILED DESCRIPTION

To make a person skilled in the art understand the solutions in the present disclosure better, the following clearly and completely describes the technical solutions in the embodiments of the present disclosure with reference to the accompanying drawings in the embodiments of the present disclosure. Apparently, the described embodiments are merely some but not all of the embodiments of the present disclosure. All other embodiments obtained by those of ordinary skill in the art based on the embodiments of the present disclosure without any creative efforts shall fall within the scope of protection of the present disclosure.

The terms “first”, “second”, “third”, “fourth”, and the like (if any) in the specification and claims of the present disclosure and the foregoing drawings are intended to distinguish between similar objects but do not necessarily indicate a specific order or sequence. It should be understood that the data used in this way are interchangeable in appropriate circumstances, so that the described embodiments of the present disclosure can be implemented in other orders than the order illustrated or described herein.

Moreover, the terms “include” and “comprise”, and any other variants thereof are intended to cover the non-exclusive inclusion. For example, a process, method, system, product, or device that includes a list of steps or modules is not necessarily limited to those expressly listed steps or modules, but may include other steps or modules not expressly listed or inherent to such a process, method, product, or device.

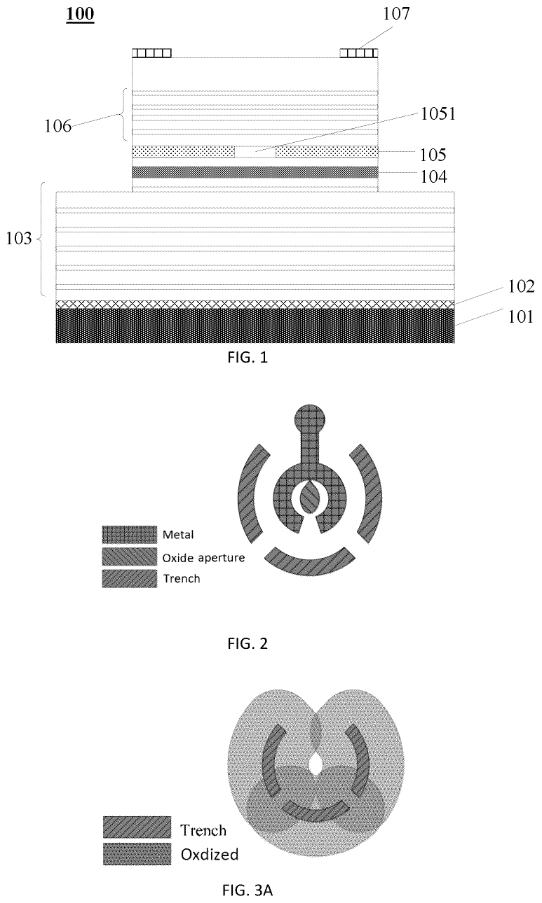

For ease of understanding and explanation, a high-speed vertical cavity surface emitting laser and an optoelectronic device with the same, and a manufacturing method provided by the embodiments of the present disclosure are detailed in detail below through FIG. 1 to FIG. 7.

FIG. 1 is a cross-sectional structure diagram of a high-speed vertical cavity surface emitting laser provided by an embodiment of the present disclosure. The high-speed vertical cavity surface emitting laser 100 includes a substrate layer 101, a first electrode layer 102, a first reflector layer 103, an active layer 104, an oxide-confined layer 105, a second reflector layer 106, and a second electrode layer 107.

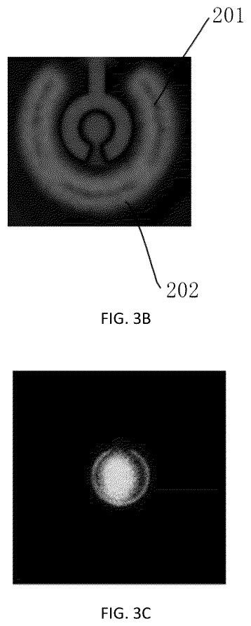

It should be noted that, in one embodiment of the present disclosure, the first electrode layer 102 may be an N-type metal electrode layer, and the second electrode layer 107 may be a P-type metal electrode layer. The oxide-confined layer 105 has a drop-shaped oxide aperture, as shown in FIG. 2. Further, FIG. 3A-3C sequentially show an oxidation simulation diagram corresponding to a drop-shaped oxide aperture, a microscope diagram corresponding to an actual chip, and a near field (NF) spot diagram provided by an embodiment of the present disclosure. In FIG. 3B, the three thin strips along center of arcs are trenches 201, which are covered by wide strip metals 202, and a notched annular metal is formed around the drop-shaped oxide aperture. In one embodiment of the present disclosure, the drop-shaped oxide aperture in the oxide-confined layer 105 can break rotational symmetry of mode distribution of a circular oxide aperture, thereby reducing generation of multiple degenerate modes at a same frequency point. In addition, the drop-shaped aperture can further reduce the adverse impact of process errors on high-speed performance of a chip, which is favorable to improving product yield. During production, there may be some difference between an actual oxidation shape and a designed shape, but compared to other shapes of apertures, the drop-shaped aperture has a higher tolerance for this difference. As a result, a drop-shaped chip on an entire wafer exhibits more consistent performance, thereby significantly reducing outliers and improving the yield of an optical flux chip array.

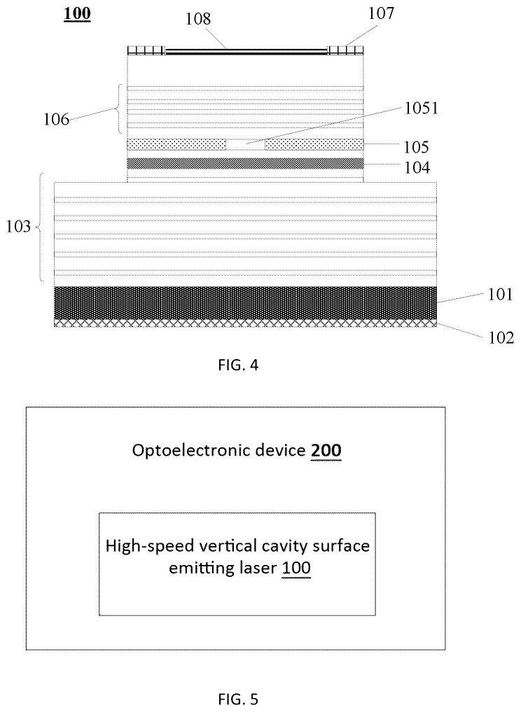

In one embodiment, as shown in FIG. 1, the first electrode layer 102, the first reflector layer 103, the active layer 104, the oxide-confined layer 105, the second reflector layer 106, and the second electrode layer 107 are sequentially stacked above the substrate layer 101. Alternatively, as shown in FIG. 4, in some embodiments of the present disclosure, the first electrode layer 102 is located below the substrate layer 101, while the first reflector layer 103, the active layer 104, the oxide-confined layer 105, the second reflector layer 106, and the second electrode layer 107 are sequentially stacked above the substrate layer 101.

In one embodiment, the first reflector layer 103 and the second reflector layer 106 may include either an N-type reflector layer or a P-type reflector layer. Further, the first reflector layer 103 and the second reflector layer 106 may include at least one of a distributed Bragg reflector (DBR) layer and a high contrast grating (HCG) layer. That is, the first reflector layer 103 and the second reflector layer 106 are both Bragg reflector layers, or the first reflector layer 103 and the second reflector layer 106 are both high contrast grating layers, or one of the first reflector layer 103 and the second reflector layer 106 is a Bragg reflector layer and the other is a high contrast grating layer.

In one embodiment, an oxide aperture 1051 is disposed in a middle position of the oxide limiting layer 105, while the active layer 104 may include either a single quantum well layer or a multiple quantum well (MQW) layer for emitting light when powered on.

In one embodiment, as shown in FIG. 4, the high-speed vertical cavity surface emitting laser 100 further includes a passivation layer 108, and the passivation layer 108 may be located in an area on the second reflector layer 106 without the second electrode layer 107. The passivation layer 108 is used for passivating an insulating protection layer, an exit window protection layer, or the like, and a material of the passivation layer 108 may include but is not limited to any one of silicon nitride (Si₃N₄) and silicon dioxide (SiO₂).

In another aspect, FIG. 5 is a structural block diagram of an optoelectronic device provided by an embodiment of the present disclosure. The optoelectronic device 200 includes the high-speed vertical cavity surface emitting laser 100 in the embodiments corresponding to FIG. 1 to FIG. 4. For example, the optoelectronic device 200 may include, but is not limited to, an optical module, an integrated optoelectronic chip, and the like.

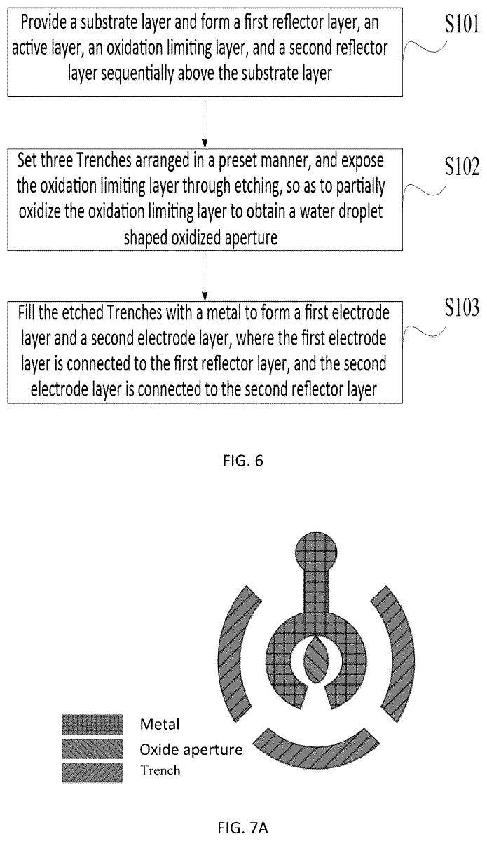

In still another aspect, FIG. 6 is a basic flowchart of a manufacturing method for a high-speed vertical cavity surface emitting laser provided by an embodiment of the present disclosure. The method may be applied to the high-speed vertical cavity surface emitting laser 100 in the embodiments corresponding to FIG. 1 to FIG. 4, and specifically includes the following steps:

S101. Providing a substrate layer and forming a first reflector layer, an active layer, an oxide-confined layer, and a second reflector layer sequentially above the substrate layer.

Taking the structure shown in FIG. 1 as an example, the first reflector layer 103, the active layer 104, the Al_{0.98}Ga_{0.02}As high-aluminum oxide-confined layer 105, and the second reflector layer 106 are cyclically and alternatively grown on the substrate layer 101 by a technology such as metal organic chemical vapor deposition (MOCVD) or molecular beam epitaxy (MBE).

S102. Setting three Trenches arranged in a preset manner, and exposing the oxide-confined layer through etching, so as to partially oxidize the oxide-confined layer to obtain a drop-shaped oxide aperture.

For example, the three Trenches arranged equidistantly or non-equidistantly may be set in one embodiment of the present disclosure, that is, distances between the Trenches are equal or unequal. A Trench pattern is obtained after photolithography, the Al_{0.98}Ga_{0.02}As high-aluminum oxide-confined layer 105 is exposed by inductively coupled plasma (ICP), and then the drop-shaped oxide aperture 1051 is obtained by wet oxidation, where the oxide aperture 1051 is disposed in the middle position of the Al_{0.98}Ga_{0.02}As high-aluminum oxide-confined layer 105.

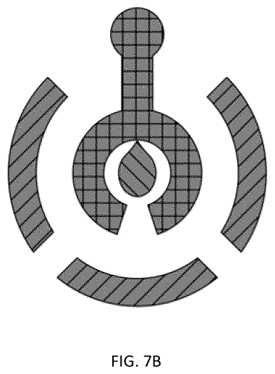

In addition, it should be noted that the sizes of the Trenches in the embodiments of the present disclosure can be adjusted according to specific process limitations and chip performance indicators. For example, the Trenches may have a width of 3 μm to 6 μm, a small spacing of 2 μm to 7 μm, and a large spacing of 15 μm to 25 μm. In the embodiments of the present disclosure, the actual aspect ratio of the oxide aperture 1051 can be changed by adjusting the size and position of the Trench, such as drop-shaped design with different aspect ratios as shown in FIG. 7A-7B. This can control the distance between the aperture and the metal, change the flow mode of current relative to the aperture, and then change the partition of carrier concentration, thereby achieving the effect of controlling the partition of multiple transverse modes. Moreover, compared to circular apertures, the Trenches in the embodiments of the present disclosure can improve the heat dissipation effect and increase chip reliability, and the large-sized Trenches can also ensure consistency in oxidation and improve product yield.

S103. Filling the etched Trenches with a metal to form a first electrode layer and a second electrode layer, where the first electrode layer is connected to the first reflector layer, and the second electrode layer is connected to the second reflector layer.

For example, in the embodiments of the present disclosure, the Trenches may be filled with the metal by magnetron sputtering, an N-type metal electrode layer corresponding to the first electrode layer 102 may be obtained by electrode evaporation, a P-type metal electrode layer corresponding to the second electrode layer 107 may be obtained by magnetron sputtering and stripping, and then the laser plated with electrodes may be placed in a rapid annealing furnace for annealing to achieve a purpose of alloy, so that good ohmic contact can be formed between the electrodes and semiconductor materials to improve electrical characteristics of the device. The first electrode layer 102 may be connected to the first reflector layer 103, and the second electrode layer 107 may be connected to the second reflector layer 106. The metal filling the Trenches may be connected to the first electrode layer 102, or the metal filling the Trenches may be connected to the second electrode layer 107. The metal may be manufactured together with the second electrode layer 107 (i.e., the P electrode layer) in order to disperse heat better and lower junction temperature. Alternatively, the metal filling the Trenches may exist independently of the two electrode layers.

It should be noted that descriptions of the same steps and content in one embodiment may be referred to for those in other embodiments, and will not be repeated here.

According to the high-speed vertical cavity surface emitting laser and the optoelectronic device with the same, and the manufacturing method provided by the embodiments of the present disclosure, the drop-shaped oxide aperture in the oxide-confined layer of the high-speed vertical cavity surface emitting laser breaks rotational symmetry of mode partition of a circular oxide aperture, and can reduce generation of multiple degenerate modes at a same frequency point, thereby reducing relative intensity noise of the laser, improving consistency of the relative intensity noise and root mean square spectral width, and significantly improving communication quality.

The above embodiments are merely used for explaining but not limiting the technical solutions of the present disclosure. Although the present disclosure is described in detail with reference to the foregoing embodiments, those of ordinary skill in the art should understand that they can still make modifications to the technical solutions described in the foregoing embodiments or make equivalent replacements to some technical features therein, without making the essences of the corresponding technical solutions depart from the spirit and scope of the technical solutions in the embodiments of the present disclosure.

What is claimed is:

1. A high-speed vertical cavity surface emitting laser, comprising: a substrate layer, a first electrode layer, a first reflector layer, an active layer, an oxide-confined layer, a second reflector layer, and a second electrode layer, wherein the first electrode layer is an N-type metal electrode layer, the second electrode layer is a P-type metal electrode layer, and
Wherein the oxide-confined layer has a drop-shaped oxide aperture, the oxide aperture is obtained by exposing the oxide-confined layer through etching three trenches arranged in a preset manner and partially oxidizing the oxide-confined layer, there is a notched annular metal around the oxide aperture, an aspect ratio of the oxide aperture is changed by adjusting sizes and positions of the trenches to control a distance between the oxide aperture and the notched annular metal and change a flow pattern of current relative to the oxide aperture and distribution of carrier concentration, and the trenches have a width of 3 μm to 6 μm, a small spacing of 2 μm to 7 μm, and a large spacing of 15 μm to 25 μm.

2. The high-speed vertical cavity surface emitting laser according to claim 1, wherein the first electrode layer, the first reflector layer, the active layer, the oxide-confined layer, the second reflector layer, and the second electrode layer are sequentially stacked above the substrate layer;
alternatively, the first electrode layer is located below the substrate layer, while the first reflector layer, the active layer, the oxide-confined layer, the second reflector layer, and the second electrode layer are sequentially stacked above the substrate layer.

3. The high-speed vertical cavity surface emitting laser according to claim 1, wherein the first reflector layer and the second reflector layer comprise at least one of a Bragg reflector layer and a high contrast grating layer.

4. The high-speed vertical cavity surface emitting laser according to claim 1, wherein the active layer comprises either a single quantum well layer or a multiple quantum well layer.

5. The high-speed vertical cavity surface emitting laser according to claim 1, wherein the oxide aperture is disposed in a middle position of the oxide-confined layer.

6. The high-speed vertical cavity surface emitting laser according to claim 2, wherein the oxide aperture is disposed in a middle position of the oxide-confined layer.

7. The high-speed vertical cavity surface emitting laser according to claim 5, wherein the first reflector layer and the second reflector layer comprise at least one of a Bragg reflector layer and a high contrast grating layer.

8. The high-speed vertical cavity surface emitting laser according to claim 5, wherein the active layer comprises either a single quantum well layer or a multiple quantum well layer.

9. The high-speed vertical cavity surface emitting laser according to claim 5, wherein the high-speed vertical cavity surface emitting laser further comprises a passivation layer, and the passivation layer is located in an area on the second reflector layer without the second electrode layer.

10. The high-speed vertical cavity surface emitting laser according to claim 2, wherein the high-speed vertical cavity surface emitting laser further comprises a passivation layer, and the passivation layer is located in an area on the second reflector layer without the second electrode layer.

11. The high-speed vertical cavity surface emitting laser according to claim 9, wherein the first reflector layer and the second reflector layer comprise at least one of a Bragg reflector layer and a high contrast grating layer.

12. The high-speed vertical cavity surface emitting laser according to claim 9, wherein the active layer comprises either a single quantum well layer or a multiple quantum well layer.

13. An optoelectronic device, comprising the high-speed vertical cavity surface emitting laser according to claim 1.

14. A manufacturing method for the high-speed vertical cavity surface emitting laser according to claim 1, wherein the method comprises:
providing the substrate layer and forming the first reflector layer, the active layer, the oxide-confined layer, and the second reflector layer sequentially above the substrate layer;
setting three trenches arranged in a preset manner, and exposing the oxide-confined layer through etching, so as to partially oxidize the oxide-confined layer to obtain the oxide aperture, wherein there is a notched annular metal around the oxide aperture, an aspect ratio of the oxide aperture is changed by adjusting sizes and positions of the trenches to control a distance between the oxide aperture and the notched annular metal and change a flow pattern of current relative to the oxide aperture and distribution of carrier concentration, and the trenches have a width of 3 μm to 6 μm, a small spacing of 2 μm to 7 μm, and a large spacing of 15 μm to 25 μm; and
filling the etched Trenches with a metal to form the first electrode layer and the second electrode layer, wherein the first electrode layer is connected to the first reflector layer, and the second electrode layer is connected to the second reflector layer.

15. The manufacturing method according to claim 14, wherein the first electrode layer, the first reflector layer, the active layer, the oxide-confined layer, the second reflector layer, and the second electrode layer are sequentially stacked above the substrate layer;
alternatively, the first electrode layer is located below the substrate layer, while the first reflector layer, the active layer, the oxide-confined layer, the second reflector layer, and the second electrode layer are sequentially stacked above the substrate layer.

16. The manufacturing method according to claim 14, wherein the first reflector layer and the second reflector layer comprise at least one of a Bragg reflector layer and a high contrast grating layer.

17. The manufacturing method according to claim 14, wherein the active layer comprises either a single quantum well layer or a multiple quantum well layer.

18. The manufacturing method according to claim 14, wherein the oxide aperture is disposed in a middle position of the oxide-confined layer.

19. The manufacturing method according to claim 14, wherein the high-speed vertical cavity surface emitting laser further comprises a passivation layer, and the passivation layer is located in an area on the second reflector layer without the second electrode layer.
